(19) United States
(12) Patent Application Publication
(10) Pub. No.: US 2025/0080071 A1
(43) Pub. Date: Mar. 6, 2025

(54) AMPLIFICATION DEVICE AND MEASUREMENT INSTRUMENT

(71) Applicant: Hitachi, Ltd., Tokyo (JP)

(72) Inventors: Ryo KUWANA, Tokyo (JP); Masahiro MASUNAGA, Tokyo (JP); Isao HARA, Tokyo (JP)

(21) Appl. No.: 18/586,892

(22) Filed: Feb. 26, 2024

(30) Foreign Application Priority Data
Sep. 6, 2023 (JP) 2023-144816

(51) Int. Cl. H03F 3/45; H03F 1/26

(52) U.S. Cl. CPC H03F 3/45475; H03F 1/26; H03F 3/45273

(57) ABSTRACT

An amplification device includes: an amplification circuit in which a differential amplification unit to which a pair of input signals is input is constituted by a pair of transistors using SiC as a channel and which amplifies and outputs a difference in voltage between the pair of input signals; and a voltage control unit which controls voltages of respective signal input terminals to which the pair of input signals is input to be equal to or less than voltages of a positive power supply and a negative power supply supplied to the amplification circuit.

### CROSS-REFERENCE TO RELATED APPLICATION

The present application claims priority from Japanese application JP2023-144816, filed on Sep. 6, 2023, the content of which is hereby incorporated by reference into this application.

### BACKGROUND OF THE INVENTION

### 1. Field of the Invention

The present invention relates to an amplification device and a measurement instrument which are used in a radiation environment.

### 2. Description of the Related Art

Various measurements of temperature, water level, radiation, and the like are required in environments, such as nuclear power plants, which are exposed to radiation. On the other hand, since a semiconductor element included in an electronic circuit of a measuring instrument is deteriorated by the ionization action of radiation, it is difficult to use the electronic circuit particularly in a high radiation environment.

One of factors of failure of the measuring instrument due to radiation is failure of an amplification device having the semiconductor element. The deterioration of an op amp (the abbreviation of an operational amplifier) generally used in the amplification device due to radiation causes a decrease in output, resulting in poor performance of the measuring instrument. Since the op amp performs an amplification operation according to a potential difference between the input terminals by using the differential amplification circuit constituted by at least two transistors, when each transistor deteriorates, the performance of the op amp is likely to deteriorate (fail).

As a method of normally operating the electronic circuit having the semiconductor element in a radiation environment, a method of changing a semiconductor material of the op amp from a conventional silicon (Si) element to a silicon carbide (SiC) element excellent in radiation resistance is effective.

Through the experiments of the inventors, it has been experimentally found that in an op amp using SiC (hereinafter, also referred to as a “SiC op amp”), a drift of an output value occurs due to an influence of external noise or radiation. JP 2020-043187 A discloses a method of reducing the drift of the output value during use by irradiating a semiconductor element using SiC with radiation in advance and incorporating the semiconductor element into an actual machine when deterioration converges.

### SUMMARY OF THE INVENTION

Although it is effective to reduce the drift of the output value of the SiC op amp by the method as described above, since the method uses the radiation source of the radiation, the management becomes complicated and the cost increases. Further, it has been newly found that it is necessary to consider a drift due to electric stress. Specifically, it has been experimentally found that in a case where an input voltage to the SiC op amp exceed 80% of a power supply voltage Vdd or a power supply voltage Vss of the SiC op amp, positive charges are trapped in defects present at an interface between an oxide film (insulation layer) and a semiconductor layer, and an offset voltage drifts. Electron-hole pairs are generated at the interface due to radiation, but electrons move at a high speed and are likely to pass through the interface. On the other hand, holes move at a slow speed and thus are likely to remain at the interface.

Unlike a conventional op amp using Si (hereinafter, referred to as “Si op amp”), the SiC op amp has many defects at the interface. Therefore, it has been newly found that it is necessary to sufficiently consider a drift of an output value (offset voltage) due to electric stress, that is, a large input voltage in order to stabilize the output of the SiC op amp.

The present invention has been made in view of the above circumstances, and an object of the present invention is to provide an amplification device and a measurement instrument which are excellent in radiation resistance and can reduce a drift of an output value without requiring complicated management.

In order to solve the above problem, an amplification device according to an aspect of the present invention includes: an amplification circuit in which a differential amplification unit to which a pair of input signals is input is constituted by a pair of transistors using SiC as a channel and which amplifies and outputs a difference in voltage between the pair of input signals; and a voltage control unit which controls voltages of respective signal input terminals to which the pair of input signals is input to be equal to or less than voltages of a positive power supply and a negative power supply supplied to the amplification circuit.

In addition, a measurement device according to an aspect of the present invention includes a measurement unit which outputs a signal according to a measurement result for a target, and an amplification device which amplifies the signal output by the measurement unit and has the above configuration.

According to the amplification device and the measurement instrument of at least one aspect of the present invention, the radiation resistance is excellent, and the drift of the output value can be reduced without requiring complicated management. Therefore, the amplification device and the measurement instrument according to an aspect of the present invention can realize an accurate and stable output in a radiation environment.

Problems, configurations, and effects other than those described above will be clarified by the following description of embodiments.

### BRIEF DESCRIPTION OF THE DRAWINGS

FIG. 1 is a diagram illustrating a basic configuration of an amplification device according to an embodiment of the present invention;

FIG. 2 is a graph illustrating an example of a drift amount of an offset voltage after application of an overvoltage in an op amp using SiC;

FIG. 3 is a diagram illustrating an example of a circuit configuration in a case where the amplification device is constituted by the op amp using SiC according to an embodiment of the present invention;

FIG. 4 is a diagram for explaining a drift threshold value with respect to an input voltage for each type of the op amp; and

FIG. 5 is a diagram illustrating a schematic configuration example of a measurement instrument using the amplification device according to an embodiment of the present invention.

### DESCRIPTION OF THE PREFERRED EMBODIMENTS

Hereinafter, examples of modes for carrying out the present invention (hereinafter, referred to as “embodiments”) will be described with reference to the accompanying drawings. In the present specification and the accompanying drawings, the same components or similar components are denoted by the same reference numerals, and redundant description may be omitted or only description focusing on a difference may be given. The number of components may be singular or plural unless otherwise specified.

### Basic Configuration of Amplification Device

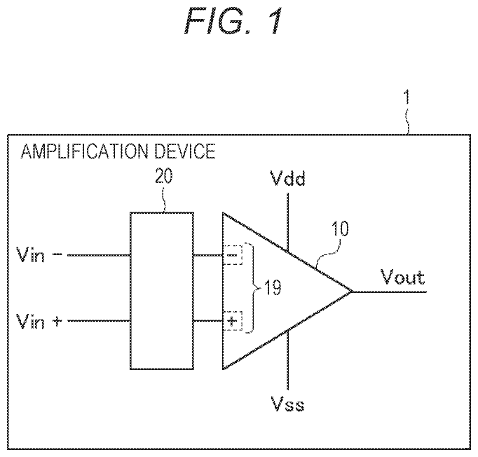

FIG. 1 is a diagram illustrating a basic configuration of an amplification device according to an embodiment of the present invention.

The amplification device 1 illustrated in FIG. 1 includes an op amp 10 and a voltage control unit 20. Vin− and Vin+ are input signals of the amplification device 1 (voltage control unit 20), and Vout is an output signal of the op amp 10.

The op amp 10 is an example of an amplification circuit using a semiconductor element. The op amp 10 is supplied with a positive power supply voltage Vdd and a negative power supply voltage Vss. The op amp 10 outputs an output signal Vout to the input signal of the differential pair.

The voltage control unit 20 is supplied with an input signal Vin− and an input signal Vin+. According to the voltages of the input signal Vin− and the input signal Vin+, the voltage control unit 20 controls the voltages (reverse phase “−”, positive phase “+”) of the input signal with respect to a differential amplification unit 19 of the op amp 10.

In a semiconductor element to be used for an electronic circuit such as the op amp, when an insulation layer is irradiated with radiation, electron-hole pairs are generated by the Compton effect, and fixed charges and interface states are formed at an interface between the insulation layer and the semiconductor layer. Due to this influence, an operation threshold voltage fluctuates, and the characteristics of the semiconductor element are deteriorated.

On the other hand, the inventors have solved the above problem by changing the material of the semiconductor element used for the op amp from conventional Si (silicon) to SiC (silicon carbide) which is a wide-band semiconductor excellent in radiation resistance performance. That is, by using SiC, the generation of an interface state due to radiation irradiation is suppressed, and the radiation resistance performance of the semiconductor element is significantly improved. Specifically, it has been confirmed that the conventional op amp using Si fails at several kGy, whereas the op amp using SiC normally operates an amplification function even at the order of MGy.

As described above, the op amp using SiC can significantly reduce the influence of radiation. However, the op amp using SiC is characterized in that many lattice defects exist at an interface between the semiconductor layer and an oxide layer as compared with the conventional op amp using Si.

Through the experiments of the inventors, it has been found that when the op amp using SiC is subjected to strong electric stress on the input voltage, positive charges are trapped in lattice defects, and an offset voltage drifts. Specifically, when a voltage of 90% or more of the absolute value of the power supply voltage Vdd (positive power supply) or the power supply voltage Vss (negative power supply) for driving the op amp is applied to the input terminal, the drift becomes remarkable. In the following description, the expression “what % of the power supply voltage” means a percentage with respect to the absolute value of the power supply voltage.

### Drift Amount of Offset Voltage After Application of Overvoltage

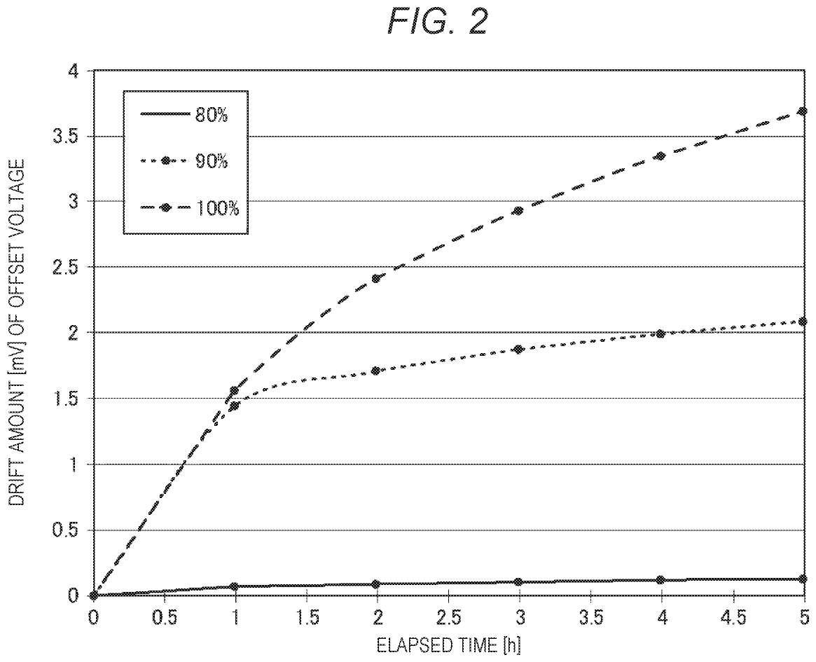

FIG. 2 is a graph illustrating an example of a drift amount of an offset voltage after application of an overvoltage in an op amp using SiC. In FIG. 2, a vertical axis represents the drift amount [mV] of the offset voltage, and a horizontal axis represents an elapsed time [h] after the overvoltage is applied.

FIG. 2 illustrates transition of the offset voltage of the op amp after voltages of 80%, 90%, and 100% with respect to the magnitudes of the power supply voltage Vdd and the power supply voltage Vss are applied to the reverse-phase and positive-phase input terminals of the SiC op amp.

It is found that in a case where the reverse-phase and positive-phase input voltages are 80% of the power supply voltage Vdd and the power supply voltage Vss, the drift amount of the offset voltage is small, and the drift converges within 1 minute.

When the reverse-phase and positive-phase input voltages exceed 80% of the power supply voltage Vdd and the power supply voltage Vss, the drift of the offset voltage is observed.

Further, in a case where the reverse-phase and positive-phase input voltages are 90% or more of the power supply voltage Vdd and the power supply voltage Vss, the drift amount of the offset voltage becomes remarkably large. In the experiment, the drift amount further increased when the input voltage exceeded 3.5 V (87.5%) with respect to the power supply voltage ±4 V, and the increase became more remarkable when the input voltage exceeded 90%. As described above, it is observed that the drift amount tends to gradually increase as the input voltage becomes larger than 80% of the power supply voltage.

Note that there is almost no difference in the drift amount between the cases of 90% and 100% within 1 minute after the application of the overvoltage, but when 1 hour or more elapses, the increase width of the drift amount in the case of 90% has smaller than that in the case of 100%. It can be seen that in the case of 90%, the converge tends to be faster than that in the case of 100%.

Based on the above results, it is preferable that the input voltages to the SiC op amp are equal to or less than the voltages of the power supply voltage Vdd and the power supply voltage Vss, or preferably equal to or less than 90% thereof. Strictly speaking, it is preferable that the input voltage is equal to or less than 87.5%.

More preferably, it is preferable that the input voltages of the SiC op amp are equal to or less than 80% of the voltages of the power supply voltage Vdd and the power supply voltage Vss in order to more stably operate the amplification device (measurement instrument). However, it is a matter of course that the input voltage is equal to or larger than the operation threshold voltage of the transistor constituting the SiC op amp.

In order to realize the SiC op amp in which the drift amount of the offset voltage is small, in the amplification device 1 according to the present embodiment, the differential amplification unit of the amplification circuit (SiC op amp) is constituted by a pair of transistors using SiC as a channel (current path). Further, the amplification device 1 is configured to include a voltage control unit which controls the voltages of respective signal input terminals (inverse input, non-inverse input) to which a pair of input signals is input so as to be equal to or less than the voltages of the power supply voltage Vdd and the power supply voltage Vss.

With the above configuration, it is possible to reduce the drift amount of the offset voltage due to the electrical stress of the SiC op amp without requiring the conventional complicated management. Therefore, under the radiation environment, the amplification device 1 can realize a stable output for a long period of time.

### Circuit Configuration in Case Where Amplification Device is Constituted by Op Amp Using SiC

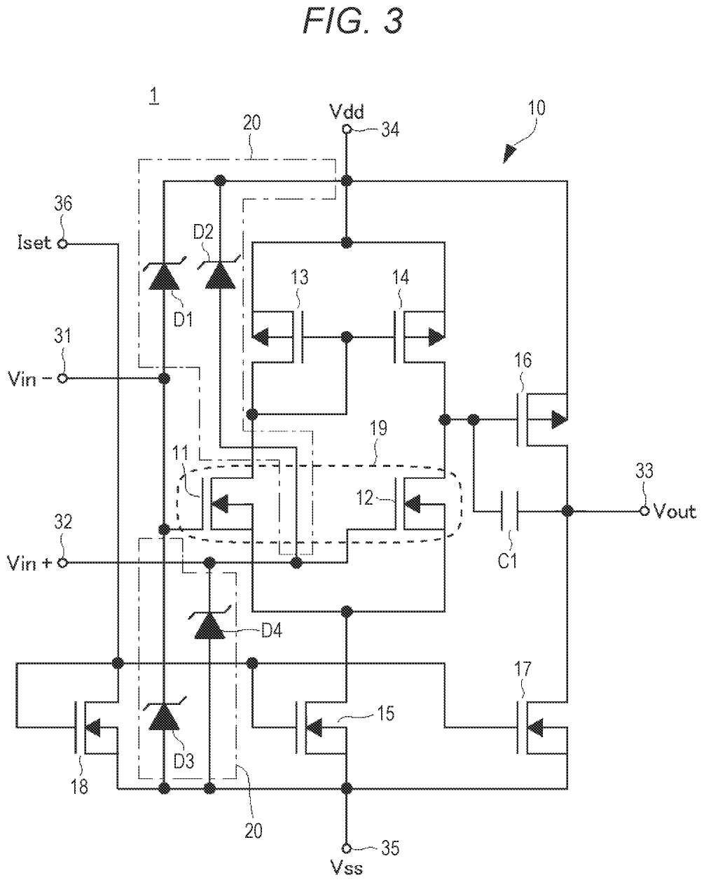

FIG. 3 is a diagram illustrating an example of a circuit configuration in a case where the amplification device 1 is constituted by the op amp 10 using SiC.

In the op amp 10, a pair of an n-type MOS field effect transistor 11 and an n-type MOS field effect transistor 12 using SiC as a channel constitutes the differential amplification unit 19 in an initial stage of a differential pair circuit unit. Hereinafter, the field effect transistor is referred to as “FET”. A gate of the n-type MOSFET 11 is connected to a signal input terminal 31 to which the input signal Vin− (inverse input) is input. In addition, the gate of the n-type MOSFET 12 is connected to a signal input terminal 32 to which the input signal Vin+ (non-inverse input) is input.

The drain of the n-type MOSFET 11 is connected to the drain of a p-type MOSFET 13 on an upper stage. The source of the p-type MOSFET 13 is connected to a power input terminal 34 to which the positive power supply voltage Vdd is supplied.

Similarly, the drain of the n-type MOSFET 12 is connected to the drain of a p-type MOSFET 14 on an upper stage. The source of the p-type MOSFET 14 is connected to the power input terminal 34 to which the positive power supply voltage Vdd is supplied.

A midpoint between the drain of the n-type MOSFET 11 and the drain of the p-type MOSFET 13 is connected to a midpoint between the gate of the p-type MOSFET 13 and the gate of the p-type MOSFET 14. That is, the p-type MOSFET 13 and the p-type MOSFET 14 constitute a current mirror circuit.

The source of the n-type MOSFET 11 is connected to the drain of the n-type MOSFET 15, and the source of the n-type MOSFET 12 is connected to the drain of the n-type MOSFET 15. Further, the source of the n-type MOSFET 15 is connected to a power input terminal 35 to which the negative power supply voltage Vss is supplied.

A midpoint between the n-type MOSFET 12 and the p-type MOSFET 14 is connected to the gate of the p-type MOSFET 16 and one end of a capacitor C1. The source of the p-type MOSFET 16 is connected to the power input terminal 34, and the drain thereof is connected to a signal output terminal 33 which outputs the output signal Vout. In addition, the other end of the capacitor C1 is also connected to the signal output terminal 33. The capacitor C1 is a capacitor for phase compensation.

The anode of a Zener diode D1 is connected to the signal input terminal 31, and the cathode of the Zener diode D1 is connected to the power input terminal 34. In addition, the anode of a Zener diode D2 is connected to the signal input terminal 32, and the cathode of the Zener diode D2 is connected to the power input terminal 34.

Further, the cathode of a Zener diode D3 is connected to the signal input terminal 31, and the anode of the Zener diode D3 is connected to the power input terminal 35. In addition, the cathode of a Zener diode D4 is connected to the signal input terminal 32, and the anode of the Zener diode D4 is connected to the power input terminal 35. The Zener diodes D1 to D4 constitute a voltage control unit 20.

The Zener diodes D1 and D3 are provided as voltage protection elements between the signal input terminal 31 and the power input terminal 34 and between the signal input terminal 31 and the power input terminal 35. Accordingly, the voltage applied to the n-type MOSFET 11 of the op amp 10 through the signal input terminal 31 can be controlled to protect the op amp 10.

Similarly, the Zener diodes D2 and D4 are provided as voltage protection elements between the signal input terminal 32 and the power input terminal 34 and between the signal input terminal 32 and the power input terminal 35. Accordingly, the voltage applied to the n-type MOSFET 12 of the op amp 10 through the signal input terminal 32 can be controlled to protect the op amp 10.

Further, the amplification device 1 includes a control terminal 36 for an idling current Iset. The control terminal 36 is connected to the drain and the gate of the n-type MOSFET 18. The source of the n-type MOSFET 18 is connected to the power input terminal 35.

In addition, the control terminal 36 is connected to the gate of the n-type MOSFET 15.

Further, the control terminal 36 is connected to the gate of the n-type MOSFET 17. The drain of the n-type MOSFET 17 is connected to the drain of the p-type MOSFET 16, and the source thereof is connected to the power input terminal 35.

The control terminal 36 for the idling current Iset is a circuit for adjusting the drive current of the op amp 10, but is not essential. The consumption current of the op amp 10 can be adjusted by the idling current Iset. As the drive current of the op amp 10 is larger, the op amp 10 is more stable, but the consumption current increases. In this regard, the drive current is adjusted by adjusting the idling current by a resistor (not illustrated) connected to the control terminal 36.

In the present embodiment, two transistors (differential amplification unit 19) which form at least a differential pair in the op amp 10 are assumed like the n-type MOSFETs 11 and 12. Note that the differential amplification unit 19 may be constituted by a pair of p-type MOSFETs instead of a pair of n-type MOSFETs. In that case, a p type and a n type are changed as appropriate for other MOSFETs. SiC is used as the semiconductor material of two MOSFETs constituting the differential amplification unit. However, the MOSFET is an example of the transistor, and another field effect transistor may be used.

Further, SiC may be used as the semiconductor material of two transistors (p-type MOSFETs 13 and 14) constituting the current mirror circuit on the upper stage side of the differential amplification unit 19. Note that the function of the current mirror circuit can be substituted by a resistor although an amplification factor decreases.

Of course, SiC may be used for other transistors constituting the op amp 10. From the viewpoint of radiation resistance performance, the other transistors are desirably constituted by SiC elements, but may be constituted by Si elements as long as a radiation dose is relatively low.

The Zener diodes D1 to D4 are set such that the voltages applied to the signal input terminals 31 and 32 do not exceed the range of the power supply voltage Vdd and the power supply voltage Vss. Specifically, in the case of the power supply voltage of Vdd=4 V and Vss=−4 V, the Zener diodes D1 to D4 are set such that the voltages of the signal input terminals 31 and 32 are not 4 V or more and −4 V or less. For example, in a case where the input signal Vin+ of 5 V is input to the amplification device 1, the voltage of the signal input terminal 32 is clamped (limited) to 4 V by the Zener diodes D2 and D4. Therefore, the non-inverse input of the op amp 10 is limited to 4 V which is the same as the power supply voltage Vdd.

The amplification device 1 according to the present embodiment described above is characterized in that a voltage protection element (voltage control unit 20) is provided in the input portion of the op amp 10 using SiC as a channel. According to the present embodiment, without requiring conventional complicated management, the drift of the offset voltage can be reduced with a simple configuration even in the radiation environment. Therefore, in the amplification device 1 including the op amp 10, a stable output can be obtained over a long period of time.

In the above configuration, the circuit elements constituting the voltage control unit 20, that is, voltage protection elements (for example, the Zener diodes D1 to D4) may be configured to be integrated in the chip of the op amp 10. With such a configuration, it is possible to reduce the drift of the offset voltage at low cost without changing the size of the conventional op amp. That is, the op amp 10 and the voltage control unit 20 are integrated into one chip as a SiC-integrated circuit (IC). In the case of one-chip, there is a cost advantage since a circuit area can be reduced.

Conversely, the voltage protection element (voltage control unit 20) may be externally attached as a peripheral circuit of the op amp 10. In that case, a circuit scale of the op amp 10 added with the voltage control unit 20 is larger than that of the conventional op amp, but there is an advantage that the value of the protection voltage can be flexibly changed. By providing the voltage control unit 20 as a peripheral circuit, it is easy to change the protection voltage (circuit constant) according to the power supply voltage for driving the op amp 10.

In the present embodiment, the Zener diode is used as the voltage protection element, but the voltage protection circuit (voltage control unit 20) can be constituted by using an element other than the Zener diode. For example, in addition to a clamp circuit (FIG. 3) using a Zener diode, a clamp circuit using a diode, a clamp circuit using a varistor, a protection circuit using a protection capacitor, or the like can be considered as the voltage protection circuit. In a case where the protection capacitor is used as the voltage protection element, capacitors are connected between the signal input terminal 31 and the ground and between the signal input terminal 32 and the ground.

In addition, in the above configuration, from the viewpoint of radiation resistance performance, it is desirable that the voltage protection element is constituted by a SiC element. However, the voltage protection element may be constituted by a Si element as long as the radiation dose is relatively low.

In the above description, the set value (set voltage) of the voltage to be protected by the voltage protection element (voltage control unit 20) is set within the range of the positive power supply voltage Vdd and the negative power supply voltage Vss, but the present invention is not limited to this example. As described above, in order to further reduce the drift of the offset voltage, the set value of the voltage protection element is desirably set to 90% or less (for example, 87.5%) of the power supply voltage Vdd and the power supply voltage Vss. More desirably, it is preferable that the set value is equal to or less than 80%.

### Type of Op Amp and Drift Occurrence Threshold Value for Input Voltage

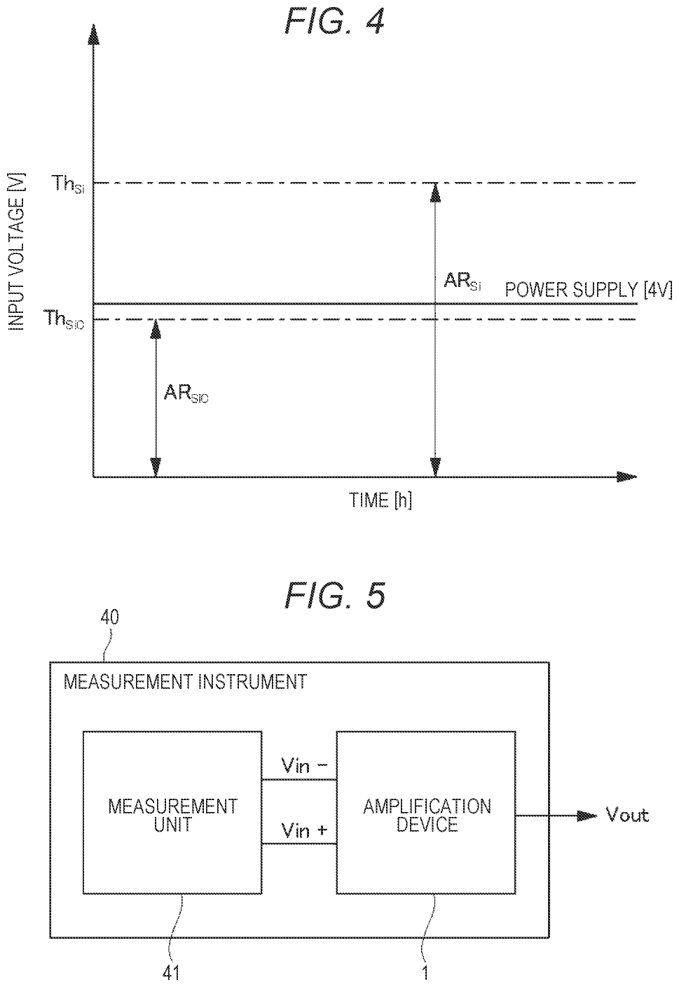

FIG. 4 is a diagram for explaining a drift occurrence threshold value with respect to the input voltage for each type of the op amp. In FIG. 4, a vertical axis represents the voltage [V] of the input signal, and a horizontal axis represents time [h].

In a conventional Si op amp, a voltage value of the input signal at which the drift of the offset voltage occurs with respect to the power supply voltage Vdd and the power supply voltage Vss (hereinafter, referred to as a “drift occurrence threshold value”) is high. The drift occurrence threshold value is a value of the input voltage at which a drift amount which is unacceptable in terms of quality or is set in advance occurs in the offset voltage of the op amp. For example, in the case of the power supply voltage of 4 V, the drift occurrence threshold value Thₛᵢ of the Si op amp is a value greatly exceeding 4 V. Therefore, in a normal application, the drift caused by the input voltage is less likely to be a problem in the Si op amp. In FIG. 4, AR_{Si} indicates an allowable input range of the Si op amp.

On the other hand, it has been experimentally found that in the SiC op amp, the drift occurs when the input signal exceeds the power supply voltage. This is considered to be caused by trapping of positive charges at the interface of the semiconductor layer of the MOSFET constituting the SiC op amp. SiC has more defects at the interface of the semiconductor layer in the vicinity of the oxide film than Si, and thus more positive charges are trapped in the defects.

In this regard, in the SiC op amp, the drift occurrence threshold value Th_{siC} is set to be equal to or less than the power supply voltage (for example, 4 V), and the input voltage is controlled to be equal to or less than the power supply voltage. Accordingly, it is possible to reduce trapping of positive charges in interface defects in the SiC op amp and to realize a stable output with a less drift of the offset voltage over a long period of time even in the radiation environment. The set value of the voltage protection element may be determined on the basis of the drift occurrence threshold value Th_{siC}. In FIG. 4, AR_{SiC} indicates an allowable input range of the SiC op amp. The allowable input range AR_{SiC} is narrower than the allowable input range AR_{Si} of the Si op amp, and has an upper limit value smaller than the power supply voltage.

Note that in a semiconductor element such as the op amp 10, SiC is used as a semiconductor having a band gap larger than that of Si, but gallium nitride (GaN), a diamond semiconductor, or the like may be used.

### Measurement Instrument Using Amplification Device of Present Invention

Next, a measurement instrument using an amplification device according to an embodiment of the present invention will be described with reference to FIG. 5.

FIG. 5 is a diagram illustrating a schematic configuration example of a measurement instrument 40 using the amplification device 1 according to an embodiment of the present invention.

The illustrated measurement instrument 40 includes a measurement unit 41 and the amplification device 1.

The measurement unit 41 is a circuit which outputs a signal according to a measurement result of a physical quantity, a characteristic, or the like of a target.

The amplification device 1 receives a pair of input signals Vin− and Vin+ output from the measurement unit 41. Then, the amplification device 1 amplifies a difference between the voltages of the input signals Vin− and Vin+ and outputs the output signal Vout. As illustrated in FIGS. 1 and 3, the positive power supply voltage Vdd and the negative power supply voltage Vss are supplied to the amplification device 1. When the voltage of the pair of input signals exceeds the power supply voltage Vdd or the power supply voltage Vss, the voltage control unit 20 (FIG. 3) controls the input voltage to be a set voltage equal to or less than the power supply voltage. The op amp 10 performs an amplification operation on the basis of the pair of input signals of which the voltage values have been adjusted by the voltage control unit 20.

Here, a pressure transmitter will be described as an example of the measurement instrument. In the pressure transmitter operating in a high radiation environment, it is required to reduce an initial drift. Specifically, the time until the output is stabilized from when the power supply of the SiC op amp is turned on may be as long as 60 minutes to 200 minutes in the SiC op amp while the time is about 10 minutes in the conventional Si op amp. The drift amount of the offset voltage is about 1 mV to several mV, and thus is small enough to be unnoticeable for some applications. However, for example, for a pressure transmitter which measures a minute differential pressure, the drift amount leads to a measurement error of about 0.1 to 0.3%.

Through the experiments of the present inventors, it has been found that the rise characteristics of the power supply voltage and the input voltage of the op amp when the power supply is turned on are influential factors in the drift of the offset voltage. Specifically, it has been experimentally found that the drift occurs when there is a timing at which the power supply voltage or the input voltage deviates from the allowable input range of the SiC op amp during several us to several ms until the power supply voltage or the input voltage is stabilized. As an example in which the input voltage deviates from the allowable input range, chattering (waveform fluctuation), noise, or the like can be considered.

On the other hand, according to the amplification device 1 having the above-described configuration, it is possible to reduce the drift of the offset voltage of the SiC op amp without requiring the conventional complicated management, and to achieve both high radiation resistance and operation stability. Therefore, an accurate and stable output can be realized in the radiation environment. Then, the amplification device 1 according to the present embodiment is applied to the measurement instrument 40, thereby contributing to improvement in the reliability of a plant operation.

The amplification device according to the present embodiment can be applied to a measurement instrument which measures a state (physical quantity or characteristic) of an object assumed to be used in the radiation environment. The measurement unit 41 may be any sensor as long as the measurement unit uses a sensing method for measuring pressure, temperature, flow rate, water level, radiation, ultrasonic wave, or the like. In addition, the measurement unit 41 may be an image sensor. Further, the measurement instrument of the present embodiment can also be applied to systems and fields such as radiation utilization equipment in a nuclear power plant or the like, medical care, and space measurement.

Note that it is desirable that the measurement unit 41 does not include an electronic circuit, or is constituted by an analog circuit relatively more resistant to radiation than a digital circuit or a wide band gap semiconductor, such as SiC, having excellent radiation resistance.

The present invention is not limited to the above-described embodiments, and it goes without saying that various other application examples and modifications can be taken without departing from the gist of the present invention described in the claims. For example, in the above-described embodiment, the configurations thereof have been described in detail and specifically in order to describe the present invention in an easy-to-understand manner, and the present invention is not necessarily limited to those including all the described components. In addition, it is also possible to add, replace, or delete other components for a part of the configuration of the embodiment.

What is claimed is:

1. An amplification device comprising:
an amplification circuit in which a differential amplification unit to which a pair of input signals is input is constituted by a pair of transistors using SiC as a channel and which amplifies and outputs a difference in voltage between the pair of input signals; and
a voltage control unit which controls voltages of respective signal input terminals to which the pair of input signals is input to be equal to or less than voltages of a positive power supply and a negative power supply supplied to the amplification circuit.

2. The amplification device according to claim 1, wherein
the voltage control unit limits each of the pair of input signals input to the differential amplification unit of the amplification circuit to be equal to or less than 90% of an absolute value of each voltage of the positive power supply and the negative power supply.

3. The amplification device according to claim 2, wherein
the voltage control unit limits each of the pair of input signals input to the differential amplification unit of the amplification circuit to be equal to or less than 80% of an absolute value of each voltage of the positive power supply and the negative power supply.

4. The amplification device according to claim 1, wherein
the voltage control unit includes
a voltage protection element which provided between a signal input terminal to which one input signal of the pair of input signals is input and each of a power input terminal to which a voltage of the positive power supply is supplied and a power input terminal to which a voltage of the negative power supply is supplied, and
a voltage protection element which provided between a signal input terminal to which another input signal of the pair of input signals is input and each of a power input terminal to which a voltage of the positive power supply is supplied and a power input terminal to which a voltage of the negative power supply is supplied, and
in a case where an input signal having a voltage exceeding a set voltage is input to each signal input terminal, causes each voltage protection element to limit a voltage of each signal input terminal to be equal to or less than voltages of the positive power supply and the negative power supply supplied to the amplification circuit.

5. The amplification device according to claim 4, wherein
in a case where an input signal of a voltage exceeding a set voltage is input to each signal input terminal, the voltage control unit causes each voltage protection element to limit the voltage of each signal input terminal to be equal to or less than 90% of an absolute value of each voltage of the positive power supply and the negative power supply.

6. The amplification device according to claim 4, wherein
in a case where an input signal of a voltage exceeding a set voltage is input to each signal input terminal, the voltage control unit causes each voltage protection element to limit the voltage of each signal input terminal to be equal to or less than 80% of an absolute value of each voltage of the positive power supply and the negative power supply.

7. The amplification device according to claim 1, wherein
the voltage control unit includes
a capacitor which is provided between a signal input terminal to which one input signal of the pair of input signals is input and ground, and
a capacitor which is provided between a signal input terminal to which another input signal of the pair of input signals is input and the ground, and
in a case where an input signal having a voltage exceeding a set voltage is input to each signal input terminal, causes each capacitor to limits the voltage of each signal input terminal to be equal to or less than voltages of the positive power supply and the negative power supply supplied to the amplification circuit.

8. The amplification device according to claim 1, wherein
the amplification circuit is an op amp.

9. The amplification device according to claim 1, wherein
a circuit element constituting the voltage control unit is integrated in a same chip as that of the amplification circuit.

10. A measurement instrument which includes a measurement unit which outputs a signal according to a measurement result for a target, and an amplification device which amplifies the signal output by the measurement unit, wherein
the amplification device includes
an amplification circuit in which a differential amplification unit to which a pair of input signals is input is constituted by a pair of transistors using SiC as a channel and which amplifies and outputs a difference in voltage between the pair of input signals; and
a voltage control unit which controls voltages of respective signal input terminals to which the pair of input signals is input to be equal to or less than voltages of a positive power supply and a negative power supply supplied to the amplification circuit.
